(19) United States
(12) Patent Application Publication
(10) Pub. No.: US 2026/0026276 A1
(43) Pub. Date: Jan. 22, 2026

(54) PLASMA ETCHING METHOD USING HEPTAFLUOROPROPYL METHYL ETHER AND HEPTAFLUOROISOPROPYL METHYL ETHER

(71) Applicant: AJOUUNIVERSITY INDUSTRY-ACADEMIC COOPERATION FOUNDATION, Suwon-si, Gyeonggi-do (KR)

(72) Inventors: Chang-Koo KIM, Seoul (KR); Sanghyun YOU, Suwon-si (KR); Yu Jong LEE, Gunpo-si (KR)

(73) Assignee: AJOU UNIVERSITY INDUSTRY-ACADEMIC COOPERATION FOUNDATION, Suwon-si, Gyeonggi-do (KR)

(21) Appl. No.: 18/997,923

(22) PCT Filed: Jul. 13, 2023
(86) PCT No.: PCT/KR2023/009992

§ 371 Date: Jan. 23, 2025

(30) Foreign Application Priority Data
Aug. 5, 2022 (KR) 10-2022-0098133
Dec. 26, 2022 (KR) 10-2022-0184992

(51) Int. Cl. H01L 21/311; C09K 13/00

(52) U.S. Cl. CPC H01L 21/31116; C09K 13/00

(57) ABSTRACT

Disclosed is a plasma etching method. The plasma etching method may comprise: a first step for vaporizing liquid heptafluoropropyl methyl ether (HFE-347mcc3) and liquid heptafluoroisopropyl methyl ether (HFE-347mmy); a second step for supplying a mixed gas containing the vaporized heptafluoropropyl methyl ether and the heptafluoroisopropyl methyl ether and a discharge gas containing argon gas to a plasma chamber in which an etching target is arranged; and a third step for discharging the discharge gas to generate plasma, and using the plasma to plasma etch the etching target.

### FIELD

The present disclosure relates to a plasma etching method using heptafluoropropyl methyl ether and heptafluoroisopropyl methyl ether with a low global warming potential as a discharge gas.

### DESCRIPTION OF RELATED ART

Demand for a structure having a high aspect ratio is increasing due to high density of an integrated circuit and miniaturization of an element in a semiconductor device. In general, the high aspect ratio structure is fabricated in an insulating layer for electrically separating the structure from a conductive layer. In order to manufacture such a high aspect ratio structure, a scheme of plasma etching silicon oxide (SiO₂) or silicon nitride (Si₃N₄) is widely used. Currently, in the plasma etching process of silicon oxide or silicon nitride, perfluorocarbon (PFC) gas such as CF₄, C₂F₆, C₃F₆, C₃F₈, and C₄F₅ is mainly used. The PFC gas generates various active species under plasma. In this regard, using CFₓ active species, a fluorocarbon thin film as a carbon-based polymer is deposited on a substrate surface, thereby protecting a mask, and serving as a source of an etching agent to improve a selectivity with respect to the mask.

However, the fluorocarbon thin film deposited during the plasma etching may interfere with diffusion of reactive ions and radicals depending on a thickness thereof, thereby lowering an etch rate. Further, excessive deposition of the fluorocarbon thin film on a wall face of an etched structure may cause etching stop, such that a target etched depth is not achieved, and, further, a diameter of a bottom of the etched structure is smaller than a diameter of the mask.

Further, PFC is one of 6 major greenhouse gases (CO₂, CH₄, N₂O, HFC, PFC, SF₆). The PFC gas is chemically stable and has a long average residence time in the atmosphere and thus a high global warming potential (GWP) value which is higher, by 6500 times or greater, than GWP of CO₂. Thus, the small amount of the PFC gas may greatly contribute to the global warming effect. In addition, as a proportion of the etching process in a semiconductor device manufacturing process increases, an annual discharge amount of the PFC gas is continuously increasing. Thus, in order to reduce the emission of PFC gas, various methods such as PFC gas decomposition, separation and collection have been employed. However, those methods have fundamental limits due to the PFC gas having the high GWP.

Therefore, there are a need for a novel etchant which may replace the conventional PFC gas, have a low GWP and thus are environmentally friendly, have an excellent etching characteristic to allow a high aspect ratio etched structure to be formed, and a need for a plasma etching method using the novel etchant.

### DISCLOSURE

### Technical Purposes

One purpose of the present disclosure is to provide a plasma etching method using heptafluoropropyl methyl ether and heptafluoroisopropyl methyl ether having a low global warming potential as a discharge gas in place of the conventional PFC gas having a high global warming potential.

### Technical Solutions

One aspect of the present disclosure provides a plasma etching method comprising a first step of vaporizing each of liquid heptafluoropropyl methyl ether (HFE-347mcc3) and liquid heptafluoroisopropyl methyl ether (HFE-347mmy): a second step of supplying a discharge gas including a mixed gas and argon gas to a plasma chamber in which an etching target is received, wherein the mixed gas includes the vaporized heptafluoropropyl methyl ether and the vaporized heptafluoroisopropyl methyl ether and; and a third step of discharging the discharge gas to generate plasma, and plasma-etching the etching target using the generated plasma.

In one embodiment, in order to vaporize the liquid heptafluoropropyl methyl ether and provide the vaporized heptafluoropropyl methyl ether to the plasma chamber, a first container receiving therein the liquid heptafluoropropyl methyl ether may be heated to a first temperature equal to or higher than a boiling point of the heptafluoropropyl methyl ether, and a connection pipe connecting the first container and the plasma chamber to each other may be heated to a second temperature higher than the first temperature.

In one embodiment, in order to vaporize the liquid heptafluoroisopropyl methyl ether and provide the vaporized heptafluoroisopropyl methyl ether to the plasma chamber, a second container receiving therein the liquid heptafluoroisopropyl methyl ether may be heated to a third temperature equal to or higher than a boiling point of the heptafluoroisopropyl methyl ether, and a connection pipe connecting the second container and the plasma chamber to each other may be heated to a fourth temperature higher than the third temperature.

In one embodiment, the mixed gas and the argon gas may be supplied to the plasma chamber at a flow rate ratio of 1:2, wherein the vaporized heptafluoropropyl methyl ether and the vaporized heptafluoroisopropyl methyl ether in the mixed gas may be supplied to the plasma chamber at a flow rate ratio of 1:3 to 3:1.

In one embodiment, a bias voltage of −800 to −1200V may be applied to a substrate supporting the etching target in the plasma chamber during the third step.

In one embodiment, the etching target may be a semiconductor substrate on which an amorphous carbon layer (ACL) is formed on a silicon substrate and a silicon oxide thin film or a silicon nitride thin film is formed thereon.

In one embodiment, the mixed gas and the argon gas may be supplied to the plasma chamber at a flow rate ratio of 1:2, wherein the vaporized heptafluoropropyl methyl ether and the vaporized heptafluoroisopropyl methyl ether in the mixed gas may be supplied to the plasma chamber at a flow rate ratio in a range of 1:2.3 to 2.3:1.

In one embodiment, after the third step, a ratio of an etch selectivity of the silicon oxide thin film or the silicon nitride thin film with respect to an etch selectivity of the silicon substrate may be 7.5 or greater.

In one embodiment, after the third step, a ratio of an etch selectivity of the silicon oxide thin film or the silicon nitride thin film with respect to an etch selectivity of the amorphous carbon layer (ACL) may be 10 or greater.

In one embodiment, a bias voltage of −800 to −1200V may be applied to a substrate supporting the etching target in the plasma chamber during the third step, wherein as a magnitude of the applied bias voltage increases, the ratio of the etch selectivity of the silicon oxide thin film or the silicon nitride thin film with respect to the etch selectivity of each of the silicon substrate and the amorphous carbon layer (ACL) may decrease.

### Technical Effects

According to the present disclosure, heptafluoropropyl methyl ether and heptafluoroisopropyl methyl ether having a low Global Warming Potential (GWP) is used as the discharge gas in the etching process, such that the etching process may be more environmentally friendly and the greenhouse gas emission may be reduced. In particular, when the PPC gas is used in a semiconductor manufacturing process, an optimal high aspect ratio etched structure may be achieved.

### BRIEF DESCRIPTION OF DRAWINGS

FIG. 1 is a schematic diagram of a plasma etching apparatus capable of performing a plasma etching method according to an embodiment of the present disclosure.

FIGS. 2 to 5 are respectively graphs showing variations in etch rates of a SiO₂ thin film, a Si₃N₄ thin film, a poly-Si, and an ACL (Amorphous Carbon Layer) based on a ratio of HFE-347mcc3 flow rate/HFE-347mmy flow rate/Ar flow rate at various bias voltages in a plasma etching process on the SiO₂ thin film, the Si₃N₄ thin film, the poly-Si, and the ACL, respectively.

FIG. 6 is a graph illustrating a ratio of an etch selectivity of a SiO₂ thin film with respect to an etch selectivity of the ACL based on a ratio of HFE-347mcc3 flow rate/HFE-347mmy flow rate/Ar flow rate at various bias voltages.

FIG. 7 is a graph illustrating a ratio of an etch selectivity of a Si₃N₄ thin film with respect to an etch selectivity of the ACL based on a ratio of HFE-347mcc3 flow rate/HFE-347mmy flow rate/Ar flow rate at various bias voltages.

FIG. 8 is a graph illustrating a ratio of an etch selectivity of a SiO₂ thin film with respect to an etch selectivity of the poly-Si based on a ratio of HFE-347mcc3 flow rate/HFE-347mmy flow rate/Ar flow rate at various bias voltages.

FIG. 9 is a graph illustrating a ratio of an etch selectivity of a Si₃N₄ thin film with respect to an etch selectivity of the poly-Si based on a ratio of HFE-347mcc3 flow rate/HFE-347mmy flow rate/Ar flow rate at various bias voltages.

### DETAILED DESCRIPTIONS

Hereinafter, an embodiment of the present disclosure will be described in detail with reference to the accompanying drawings. The present disclosure may be variously modified and may take many forms. Thus, specific embodiments will be illustrated in the drawings and described in detail herein. However, the specific embodiments are not intends to limit the present disclosure thereto. It should be understood that all changes, equivalents thereto, or substitutes therewith are included in a scope and spirit of the present disclosure. In describing the drawing, similar reference numerals are used for similar components.

The terminology used herein is for the purpose of describing particular embodiments only and is not intends to be limiting of the present disclosure. As used herein, the singular forms “a” and “an” are intends to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or greater other features, integers, operations, elements, components, and/or portions thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

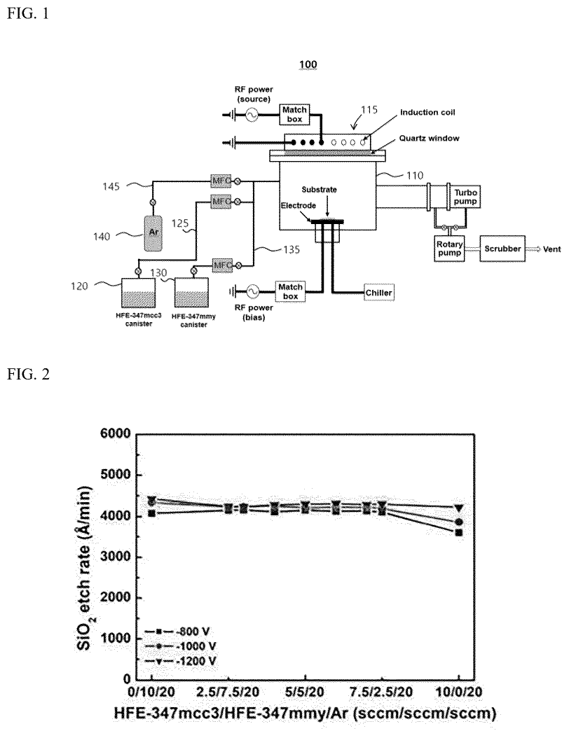

FIG. 1 is a schematic diagram of a plasma etching apparatus capable of performing a plasma etching method according to an embodiment of the present disclosure.

Referring to FIG. 1, the plasma etching method according to an embodiment of the present disclosure may include providing a discharge gas containing a mixed gas of heptafluoropropyl methyl ether (HFE-347mcc3) and heptafluoroisopropyl methyl ether (HFE-347mmy) and argon (Ar) gas into a plasma chamber in which an etching target is disposed, such that plasma etching on the etching target is performed.

The etching target is not particularly limited, but may be a silicon oxide layer, a silicon nitride layer, or the like, which generally functions as an insulating layer in a semiconductor device manufacturing process. For example, the etching target may be silicon oxide such as silicon dioxide (SiO₂) or silicon nitride such as Si₃N₄.

The heptafluoropropyl methyl ether (HFE-347 mcc3) is a substance composed of 4 carbons, 3 hydrogen, 1 oxygen, and 7 fluorine, and may have a boiling point of about 34° C. and thus may be present in a liquid state at room temperature.

The heptafluoroisopropyl methyl ether (HFE-347mmy) is a substance composed of 4 carbons, 3 hydrogen, 1 oxygen, and 7 fluorine, and may have a boiling point of about 29° C. and thus may be present in a liquid state at room temperature.

Specific physical properties of the mixed gas used in the present disclosure are shown in Table 1 as set forth below.

TABLE 1

| | | | Boiling | |
|---|---|---|---|---|
| | Chemical | Molecular | Point | |
| Chemical Name | Formula | Weight(g/mol) | (° C.) | GWP |
| Heptafluoropropyl | C₄H₃F₇O | 200 | 34 | 530 |
| methyl ether (HFE- | | | | |
| 347mcc3) | | | | |
| Heptafluoroisopropyl | C₄H₃F₇O | 200 | 29 | 353 |
| methyl ether (HFE- | | | | |
| 347mmy) | | | | |

In one embodiment, the plasma etching method according to the embodiment of the present disclosure may be performed using the etching apparatus shown in FIG. 1. In one embodiment, the etching apparatus 100 may include a plasma chamber 110, a first container 120, a second container 130 and a third container 140.

The plasma chamber 110 may be coupled to a plasma source 115 and may have a discharge space receiving an etching target (wafer) therein. The discharge space may receive the discharge gas from the first to third containers 120, 130, and 140, and the plasma source 115 may apply a discharge voltage to the discharge gas to generate plasma.

The first to third containers 120, 130, and 140 may be connected to the plasma chamber 110 via first to third connection pipes 125, 135, and 145, respectively. Heptafluoropropyl methyl ether (HFE-347mcc3) in a liquid state may be received in the first container 120, heptafluoroisopropyl methyl ether (HFE-347mmy) in a liquid state may be received in the second container 130, and the argon gas may be received in the third container 140.

The heptafluoropropyl methyl ether (HFE-347mcc3) received in the first container 120 has a boiling point of 34° C. and exists in a liquid phase at room temperature. Thus, in order to uniformly introduce the heptafluoropropyl methyl ether (HFE-347mcc3) in the liquid state into the plasma chamber 110, the heptafluoropropyl methyl ether (HFE-347mcc3) may be vaporized and then provided to the discharge space of the plasma chamber 110.

In an embodiment, the vaporization of the heptafluoropropyl methyl ether (HFE-347mcc3) may be performed by heating the first container 120 receiving therein the liquid heptafluoropropyl methyl ether (HFE-347mcc3) and the first connecting pipe 125 connecting the first container 120 and the plasma chamber 110 to each other to a temperature equal to or higher than the boiling point of the heptafluoropropyl methyl ether (HFE-347mcc3). In one example, in an embodiment, in order to prevent the flow rate of the heptafluoropropyl methyl ether (HFE-347 mcc3) to be provided to the plasma chamber 110 from fluctuating due to the droplet splash, the first container 120 may be heated to a first temperature that is a temperature equal to or higher than the boiling point of the heptafluoropropyl methyl ether (HFE-347 mcc3), and the first connection pipe 125 may be heated to a second temperature higher than the first temperature. For example, the first container 120 may be heated to a temperature of about 70 to 80° C. using a heating jacket, and the first connection pipe 125 may be heated to a temperature of about 85 to 95° C. In one example, a mass flow controller may be installed at the outlet of the first connection pipe 125 so as to provide the vaporized heptafluoropropyl methyl ether (HFE-347mcc3) at a constant flow rate to the discharge space of the plasma chamber 110.

The heptafluoroisopropyl methyl ether (HFE-347mmy) received in the second container 130 has a boiling point of 29° C. and thus is present in a liquid phase at room temperature. Thus, in order to uniformly introduce the heptafluoroisopropyl methyl ether (HFE-347mmy) in the liquid state into the plasma chamber 110, the heptafluoroisopropyl methyl ether (HFE-347mmy) may be vaporized and then provided to the discharge space of the plasma chamber 110.

In an embodiment, the vaporization of the heptafluoroisopropyl methyl ether (HFE-347mmy) may be performed by heating the second container 130 receiving therein the liquid heptafluoroisopropyl methyl ether (HFE-347mmy) and the second connecting pipe 135 connecting the second container 130 and the plasma chamber 110 to each other to a temperature equal to or higher than the boiling point of the heptafluoroisopropyl methyl ether (HFE-347mmy). In one example, in an embodiment, in order to prevent the flow rate of the heptafluoroisopropyl methyl ether (HFE-347mmy) to be provided to the plasma chamber 110 from fluctuating due to the droplet splash, the second container 130 may be heated to a third temperature that is a temperature equal to or higher than the boiling point of the heptafluoroisopropyl methyl ether (HFE-347mmy), and the second connection pipe 135 may be heated to a fourth temperature higher than the third temperature. For example, the second container 130 may be heated to a temperature of about 70 to 80° C. using a heating jacket, and the first connection pipe 125 may be heated to a temperature of about 85 to 95° C. In one example, a mass flow controller may be installed at the outlet of the second connection pipe 135 so as to provide the vaporized heptafluoroisopropyl methyl ether (HFE-347mmy) at a constant flow rate to the discharge space of the plasma chamber 110.

The argon gas contained in the third container 140 may be provided to the discharge space of the plasma chamber 110 through the third connection pipe 145 different from the first and second connection pipes 125 and 135.

According to the present disclosure, when the Ar gas and the mixed gas of heptafluoropropyl methyl ether (HFE-347mcc3) and heptafluoroisopropyl methyl ether (HFE-347mmy) are supplied to the discharge space of the plasma chamber 110 and then plasma is generated, a plasma density may be increases, and anisotropic etching may be performed on the etching target via ion bombardment. Specifically, when electropositive Ar is added to electronegative fluorocarbon plasma, the plasma density is improved, such that decomposition of precursors such as heptafluoropropyl methyl ether (HFE-347mcc3) and heptafluoroisopropyl methyl ether (HFE-347mmy) is increases, thereby having a great influence on gas phase and surface chemistry. For example, a typical change in the surface chemistry due to the addition of Ar is a decrease in a fluorine content in a steady state fluorocarbon formed at the surface. In addition, since the Ar is electropositive, it is accelerated to a wafer having a negative charge to perform the ion bombardment. Accordingly, the anisotropic etching may be performed when a hole is formed in the wafer.

In an embodiment of the present disclosure, when the etching target is silicon oxide or silicon nitride, the mixed gas and the Ar gas may be provided to the discharge space of the plasma chamber 110 at a flow rate ratio of about 1:2. The vaporized heptafluoropropyl methyl ether and the vaporized heptafluoroisopropyl methyl ether in the mixed gas may be provided to the discharge space of the plasma chamber 110 at a flow rate ratio of 1:3 (=2.5:7.5) to 3:1 (=7.5:2.5).

In an embodiment of the present disclosure, when an object to be etched is a semiconductor substrate in which an amorphous carbon layer (ACL) is formed on a silicon substrate, and a silicon oxide thin film or a silicon nitride thin film is formed thereon, the mixed gas and the Ar gas may be provided to the discharge space of the plasma chamber 110 at a flow rate ratio of about 1:2. The vaporized heptafluoropropyl methyl ether and the vaporized heptafluoroisopropyl methyl ether in the mixed gas may be provided to the discharge space of the plasma chamber 110 at a flow rate ratio of 1:2.3 (=3:7) to 2.3:1 (=7:3).

When the ratio of the flow rate of the vaporized heptafluoropropyl methyl ether and the flow rate of the vaporized heptafluoroisopropyl methyl ether in the mixed gas is out of the flow rate ratio of 1:2.3 to 2.3:1, there may be a problem in that the etch selectivity of the silicon oxide thin film or the silicon nitride thin film with respect to an etch selectivity of each of the silicon substrate and the amorphous carbon layer (ACL) is lowered. For example, the vaporized heptafluoropropyl methyl ether and the vaporized heptafluoroisopropyl methyl ether in the mixed gas may be provided to the discharge space of the plasma chamber 110 at a flow rate ratio of about 1:2.3 (7:3) to 2.3:1 (3:7), or about 1:1.5 (=4:6) to 1.5:1 (=6:4), most preferably about 1:1 (=5:5).

In an embodiment, when the ratio of the flow rate of the vaporized heptafluoropropyl methyl ether and the flow rate of the vaporized heptafluoroisopropyl methyl ether in the mixed gas is 1:2.3 to 2.3:1 and the mixed gas thereof is supplied to the plasma chamber 110 at this flow rate, a ratio of the etch selectivity of the silicon oxide thin film or the silicon nitride thin film with respect to an etch selectivity of the silicon substrate may be 7.5 or greater, and a ratio of the etch selectivity of the silicon oxide thin film or the silicon nitride thin film with respect to an etch selectivity of the Amorphous Carbon Layer (ACL) may be 10 or greater.

In one example, in the plasma etching method according to an embodiment of the present disclosure, a bias voltage applied to a substrate supporting the etching target may be a voltage of about −800V to −1200V. When the bias voltage is lower than −800V, an etch rate of the etching target may be excessively low. When the bias voltage is greater than −1200V, an additional improvement in the etch rate may not occur and only power consumption may be increases.

In an embodiment, when the etching target is a semiconductor substrate in which an Amorphous Carbon Layer (ACL) is formed on a silicon substrate and a silicon oxide thin film or a silicon nitride thin film is formed thereon, a ratio of an etch selectivity of the silicon oxide thin film or the silicon nitride thin film with respect to an etch selectivity of each of each of the silicon substrate and the amorphous carbon layer (ACL) may decrease as the applied bias voltage increases under a supply condition of the mixed gas at the same flow rate ratio. This is because, when the bias voltage within the above range is applied, and as the bias voltage increases, the increase in the etch rate of each of each of the silicon substrate and the amorphous carbon layer (ACL) is greater than the increase in the etch rate of the silicon oxide thin film or the silicon nitride thin film.

In addition, in the plasma etching method according to the embodiment of the present disclosure, the source power applied to the plasma source 115 to generate plasma of the discharge gas may be about 200 W or greater. When the source power is lower than 200 W, there may be a problem in that the etch rate of the etching target is significantly low. In one example, in order to reduce power consumption, the source power applied to the plasma source 115 may be about 200 or greater and lower than 1000 W.

According to the present disclosure, since the plasma etching process is performed by supplying the mixture gas of heptafluoropropyl methyl ether (HFE-347mcc3) and heptafluoroisopropyl methyl ether (HFE-347mmy) having a Global Warming Potential (GWP) significantly lower than that of a conventional PFC gas together with the Ar gas as the discharge gas, the discharge of a greenhouse gas may be significantly reduced compared to a plasma etching process using the conventional PFC gas, and the plasma etching may be performed to exhibit excellent etching characteristics.

In particular, according to the plasma etching process of the present disclosure, each of the ratio of the etch selectivity of the silicon oxide thin film with respect to an etch selectivity of each of the silicon substrate and the amorphous carbon layer (ACL) and the ratio of the etch selectivity of the silicon nitride thin film with respect to an etch selectivity of each of the silicon substrate and the amorphous carbon layer (ACL) is high. Thus, when the plasma etching is performed using a hole pattern mask including the amorphous carbon layer (ACL) disposed on the etching target, a high aspect ratio etched structure in which a diameter of the hole pattern mask and a diameter of the etched structure are substantially equal to each other may be formed. A more detailed description thereof will be described below with reference to embodiments of the present disclosure.

Hereinafter, more specific examples and experimental examples will be described. However, the following examples are only some implementations of the present disclosure, and the scope of the present disclosure is not limited to the following examples.

### EXAMPLE

Plasma etching is performed on each of the ACL, the SiO₂ thin film, and the Si₃N₄ thin film formed on the surface of the silicon substrate under various conditions using a mixture gas of heptafluoropropyl methyl ether, heptafluoroisopropyl methyl ether, and argon as a discharge gas. At this time, when the heptafluoropropyl methyl ether and the heptafluoroisopropyl methyl ether are vaporized and supplied to the etching chamber, a first canister receiving therein the liquid heptafluoropropyl methyl ether is heated to 75° C., and a connecting line connecting the first canister and the etching chamber to each other is heated to 90° C. In addition, a second canister containing therein the liquid heptafluoroisopropyl methyl ether is heated to 75° C., and a connecting line connecting the second canister and the etching chamber to each other is heated to 90° C.

### Experimental Example 1: Analysis of Etching Rate Based on Ratio of HFE-347mcc3 Flow Rate/HFE-347mmy Flow Rate/Ar Flow Rate

FIGS. 2 to 5 are respectively graphs showing variations in etch rates of a SiO₂ thin film, a Si₃N₄ thin film, a poly-Si, and an ACL (Amorphous Carbon Layer) based on a ratio of HFE-347mcc3 flow rate/HFE-347mmy flow rate/Ar flow rate at various bias voltages in a plasma etching process on the SiO₂ thin film, the Si₃N₄ thin film, the poly-Si, and the ACL, respectively. The etch rate is calculated based on a measuring result of a thickness of the thin film before and after the plasma etching process.

TABLE 2

| Source | Bias | | | | Electrode |
|---|---|---|---|---|---|
| Power | Voltage | | | Pressure | Temperature |
| (W) | (V) | Discharge Gas | Flow Rate (sccm) | (mTorr) | (° C.) |
| 250 | −800, | X/Y/Z | 1. X/Y/Z = 0/10/20 | 10 | 15 |
| | −1000, | X: HFE-347mcc3 | 2. X/Y/Z = 2.5/7.5/20 | | |
| | −1200 | Y: HFE-347mmy | 3. X/Y/Z = 3/7/20 | | |
| | | Z: Ar | 4. X/Y/Z = 4/6/20 | | |
| | | | 5. X/Y/Z = 5/5/20 | | |
| | | | 6. X/Y/Z = 6/4/20 | | |
| | | | 7. X/Y/Z = 7/3/20 | | |
| | | | 8. X/Y/Z = 7.5/2.5/20 | | |
| | | | 9. X/Y/Z = 10/0/20 | | |

First, referring to FIG. 2 showing a result of measuring the etch rate of SiO₂, it is identified that the etch rate of the SiO₂ thin film at all ratios of HFE-347mcc3 flow rate/HFE-347mmy flow rate/Ar flow rate increases as the bias voltage increases.

In one example, at a constant bias voltage, the etch rate of the SiO₂ thin film based on a ratio of the HFE-347mcc3 flow rate/HFE-347mmy flow rate/Ar flow rate is almost constant at 0/10/20 to 7.5/2.5/20 sccm, and decreases at 10/0/20 sccm.

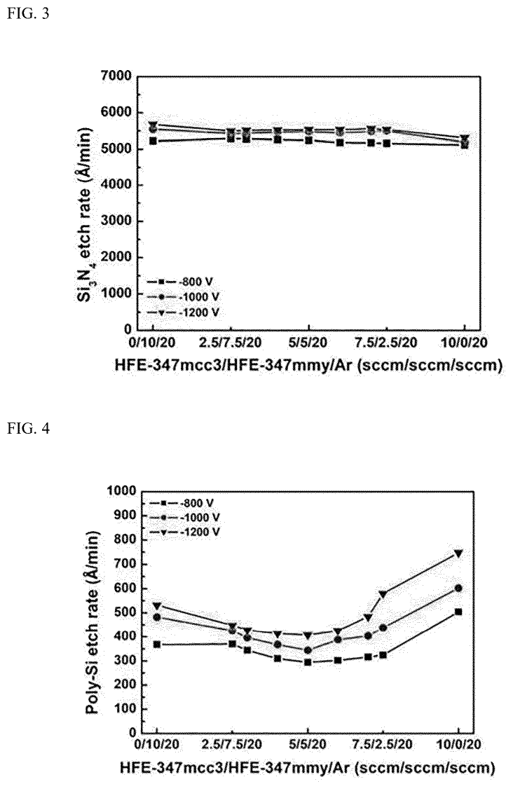

Referring to FIG. 3 which is a result of measuring the etch rate of Si₃N₄, the etch rate of the Si₃N₄ thin film at all ratios of HFE-347mcc3 flow rate/HFE-347mmy flow rate/Ar flow rate increases as the bias voltage increases.

In one example, at a constant bias voltage, the etch rate of the Si₃N₄ thin film based on a ratio of the HFE-347mcc3 flow rate/HFE-347mmy flow rate/Ar flow rate is almost constant at 0/10/20 to 7.5/2.5/20 sccm, and decreases at 10/0/20 sccm.

Referring to FIG. 4 which is a result of measuring the poly-Si etch rate, it is identified that the etch rate of the poly-Si at all ratios of the HFE-347mcc3 flow rate/HFE-347mmy flow rate/Ar flow rate increases as the bias voltage increases.

In one example, at a constant bias voltage, the etch rate of the poly-Si based on a ratio of the HFE-347mcc3 flow rate/HFE-347mmy flow rate/Ar flow rate tends to decrease as HFE-347mcc3 flow rate increases in the range of 0/10/20 to May 5, 2020 sccm, and tends to increase as HFE-347mcc3 flow rate increases in the range of Jun. 4, 2020 to 10/0/20 sccm.

Referring to FIG. 5 which is a result of measuring the ACL etch rate, it is identified that the etch rate of the ACL at all ratios of the HFE-347mcc3 flow rate/HFE-347mmy flow rate/Ar flow rate increases as the bias voltage increases.

In one example, at a constant bias voltage, the etch rate of the ACL based on a ratio of the HFE-347mcc3 flow rate/HFE-347mmy flow rate/Ar flow rate tends to decrease as the HFE-347mcc3 flow rate increases in the range of 0/10/20 to May 5, 2020 sccm, and tends to increase as the HFE-347mcc3 flow rate increases in the range of Jun. 4, 2020 to 10/0/20 sccm.

### Experimental Example 2: Analysis of Ratio of Etch Selectivity of SiO₂/the Etch Selectivity of ACL and Ratio of Etch Selectivity of Si₃N₄/the Etch Selectivity of ACL Based on Ratio of HFE-347mcc3 Flow Rate/HFE-347mmy Flow Rate/Ar Flow Rate

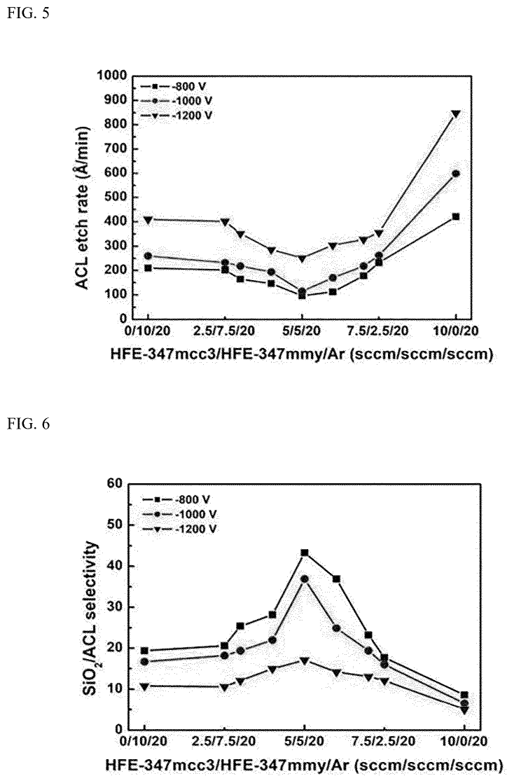

FIG. 6 is a graph showing the ratio of the etch selectivity of a SiO₂ thin film with respect to an etch selectivity of the ACL based on a ratio of HFE-347mcc3 flow rate/HFE-347mmy flow rate/Ar flow rate at various bias voltages under the conditions as described in Table 2.

Referring to FIG. 6, at a constant bias voltage, the ratio of the etch selectivity of SiO₂/the etch selectivity of ACL based on a ratio of the HFE-347mcc3 flow rate/HFE-347mmy flow rate/Ar flow rate tends to increase as the HFE-347mcc3 flow rate increases in the range of 0/10/20 to May 5, 2020 sccm, and decreases as the HFE-347mcc3 flow rate increases in the range of Jun. 4, 2020 to 10/0/20 sccm. The ratio of the etch selectivity of SiO₂/the etch selectivity of ACL is highest when the ratio of HFE-347mcc3 flow rate/HFE-347mmy flow rate/Ar flow rate is May 5, 2020 sccm.

On the other hand, as the bias voltage increases, the increase in the ACL etch rate is greater than the increase in the SiO₂ etch rate, and thus the ratio of the etch selectivity of SiO₂/the etch selectivity of ACL decreases as the bias voltage increases.

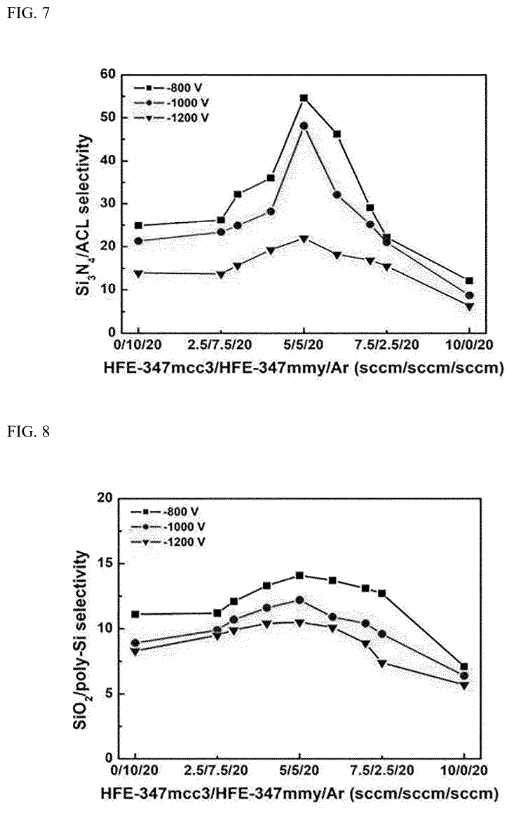

FIG. 7 is a graph showing the ratio of the etch selectivity of the Si₃N₄ thin film with respect to an etch selectivity of the ACL based on a ratio of the HFE-347mcc3 flow rate/HFE-347mmy flow rate/Ar flow rate at various bias voltages under the conditions as described in Table 2.

Referring to FIG. 7, at a constant bias voltage, the ratio of the etch selectivity of Si₃N₄/the etch selectivity of ACL based on a ratio of the HFE-347mcc3 flow rate/HFE-347mmy flow rate/Ar flow rate tends to increase as the HFE-347mcc3 flow rate increases in the range of 0/10/20 to May 5, 2020 sccm, and decreases as the HFE-347mcc3 flow rate increases in the range of Jun. 4, 2020 to 10/0/20 sccm. The ratio of the etch selectivity of Si₃N₄/the etch selectivity of ACL is highest when the ratio of HFE-347mcc3 flow rate/HFE-347mmy flow rate/Ar flow rate is May 5, 2020 sccm.

On the other hand, as the bias voltage increases, the increase in the ACL etch rate is greater than the increase in the Si₃N₄ etch rate. Thus, as the bias voltage increases, the ratio of etch selectivity of Si₃N₄/the etch selectivity of ACL decreases.

### Experimental Example 3: Analysis of Ratio of Etch Selectivity of SiO₂/the Etch Selectivity of the Poly-Si and Ratio of Etch Selectivity of Si₅N₄/Etch Selectivity of the Poly-Si Based on Ratio of HFE-347mcc3 Flow Rate/HFE-347mmy Flow Rate/Ar Flow Rate

FIG. 8 is a graph showing the ratio of the etch selectivity of a SiO₂ thin film with respect to an etch selectivity of the poly-Si based on a ratio of HFE-347mcc3 flow rate/HFE-347mmy flow rate/Ar flow rate at various bias voltages under the conditions as described in Table 2.

Referring to FIG. 8, at a constant bias voltage, the ratio of the etch selectivity of SiO₂/the etch selectivity of the poly-Si based on a ratio of the HFE-347mcc3 flow rate/HFE-347mmy flow rate/Ar flow rate tends to increase as the HFE-347mcc3 flow rate increases in the range of 0/10/20 to May 5, 2020 sccm, and decreases as the HFE-347mcc3 flow rate increases in the range of Jun. 4, 2020 to 10/0/20 sccm. The ratio of the etch selectivity of SiO₂/the etch selectivity of the poly-Si is highest when the ratio of HFE-347mcc3 flow rate/HFE-347mmy flow rate/Ar flow rate is May 5, 2020 sccm.

On the other hand, as the bias voltage increases, the increase in the poly-Si etch rate is greater than the increase in the SiO₂ etch rate, and thus the ratio of the etch selectivity of SiO₂/the etch selectivity of the poly-Si decreases as the bias voltage increases.

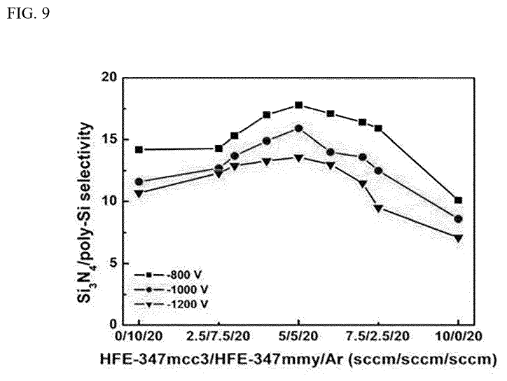

FIG. 9 is a graph showing the ratio of the etch selectivity of the Si₃N₄ thin film with respect to the etch selectivity of the poly-Si based on a ratio of the HFE-347mcc3 flow rate/HFE-347mmy flow rate/Ar flow rate at various bias voltages under the conditions as described in Table 2.

Referring to FIG. 9, at a constant bias voltage, the ratio of the etch selectivity of Si₃N₄/the etch selectivity of the poly-Si based on a ratio of the HFE-347mcc3 flow rate/HFE-347mmy flow rate/Ar flow rate tends to increase as the HFE-347mcc3 flow rate increases in the range of 0/10/20 to May 5, 2020 sccm, and decreases as the HFE-347mcc3 flow rate increases in the range of Jun. 4, 2020 to 10/0/20 sccm. The ratio of the etch selectivity of Si₃N₄/the etch selectivity of the poly-Si is highest when the ratio of HFE-347mcc3 flow rate/HFE-347mmy flow rate/Ar flow rate is May 5, 2020 sccm.

On the other hand, as the bias voltage increases, the increase in the poly-Si etch rate is greater than the increase in the Si₃N₄ etch rate. Thus, as the bias voltage increases, the ratio of the etch selectivity of Si₃N₄/the etch selectivity of the poly-Si etching selectivity decreases.

As a result, it is identified that, in particular, when the ratio of HFE-347mcc3 flow rate/HFE-347mmy flow rate/Ar flow rate is in range of 3:7:20 to 7:3:20, the ratio of the etch selectivity of each of Si₃N₄ and SiO₂ relative to the etch selectivity of each of the poly-Si and ACL is high.

Although the present disclosure has been described above with reference to the preferred embodiments of the present disclosure, those skilled in the art will understand that the present disclosure can be variously modified and changed within the scope not departing from the spirit and scope of the present disclosure described in the following patent claims.

### REFERENCE NUMERALS

100: Etching apparatus
110: Plasma chamber
115: Plasma source
120: First container
125: First connection pipe
130: Second container
135: Second connection pipe
140: Third container
145: Third connection pipe

1. A plasma etching method comprising:
a first step of vaporizing each of liquid heptafluoropropyl methyl ether (HFE-347mcc3) and liquid heptafluoroisopropyl methyl ether (HFE-347mmy);
a second step of supplying a discharge gas including a mixed gas and argon gas to a plasma chamber in which an etching target is received, wherein the mixed gas includes the vaporized heptafluoropropyl methyl ether and the vaporized heptafluoroisopropyl methyl ether and; and
a third step of discharging the discharge gas to generate plasma, and plasma-etching the etching target using the generated plasma.

2. The plasma etching method of claim 1, wherein in order to vaporize the liquid heptafluoropropyl methyl ether and provide the vaporized heptafluoropropyl methyl ether to the plasma chamber, a first container receiving therein the liquid heptafluoropropyl methyl ether is heated to a first temperature equal to or higher than a boiling point of the heptafluoropropyl methyl ether, and a connection pipe connecting the first container and the plasma chamber to each other is heated to a second temperature higher than the first temperature.

3. The plasma etching method of claim 1, wherein in order to vaporize the liquid heptafluoroisopropyl methyl ether and provide the vaporized heptafluoroisopropyl methyl ether to the plasma chamber, a second container receiving therein the liquid heptafluoroisopropyl methyl ether is heated to a third temperature equal to or higher than a boiling point of the heptafluoroisopropyl methyl ether, and a connection pipe connecting the second container and the plasma chamber to each other is heated to a fourth temperature higher than the third temperature.

4. The plasma etching method of claim 1, wherein the mixed gas and the argon gas are supplied to the plasma chamber at a flow rate ratio of 1:2,
wherein the vaporized heptafluoropropyl methyl ether and the vaporized heptafluoroisopropyl methyl ether in the mixed gas are supplied to the plasma chamber at a flow rate ratio of 1:3 to 3:1.

5. The plasma etching method of claim 1, wherein a bias voltage of −800 to −1200V is applied to a substrate supporting the etching target in the plasma chamber during the third step.

6. The plasma etching method of claim 1, wherein the etching target is a semiconductor substrate on which an amorphous carbon layer (ACL) is formed on a silicon substrate and a silicon oxide thin film or a silicon nitride thin film is formed thereon.

7. The plasma etching method of claim 6, wherein the mixed gas and the argon gas are supplied to the plasma chamber at a flow rate ratio of 1:2,
wherein the vaporized heptafluoropropyl methyl ether and the vaporized heptafluoroisopropyl methyl ether in the mixed gas are supplied to the plasma chamber at a flow rate ratio in a range of 1:2.3 to 2.3:1.

8. The plasma etching method of claim 7, wherein after the third step, a ratio of an etch selectivity of the silicon oxide thin film or the silicon nitride thin film with respect to an etch selectivity of the silicon substrate is 7.5 or greater.

9. The plasma etching method of claim 7, wherein after the third step, a ratio of an etch selectivity of the silicon oxide thin film or the silicon nitride thin film with respect to an etch selectivity of the amorphous carbon layer (ACL) is 10 or greater.

10. The plasma etching method of claim 8, wherein a bias voltage of −800 to −1200V is applied to a substrate supporting the etching target in the plasma chamber during the third step,
wherein as a magnitude of the applied bias voltage increases, the ratio of the etch selectivity of the silicon oxide thin film or the silicon nitride thin film with respect to the etch selectivity of each of the silicon substrate and the amorphous carbon layer (ACL) decreases.
